(19) United States
(12) Patent Application Publication
(10) Pub. No.: US 2024/0337013 A1
(43) Pub. Date: Oct. 10, 2024

(54) CHEMICAL LIQUID, MANUFACTURING METHOD OF MODIFIED SUBSTRATE, MANUFACTURING METHOD OF LAMINATE, AND CHEMICAL LIQUID CONTAINER

(71) Applicant: FUJIFILM Corporation, Tokyo (JP)

(72) Inventors: Atsushi Mizutani, Haibara-gun (JP); Akihiro Hakamata, Haibara-gun (JP); Koichi Sato, Haibara-gun (JP)

(73) Assignee: FUJIFILM Corporation, Tokyo (JP)

(21) Appl. No.: 18/746,869

(22) Filed: Jun. 18, 2024

Related U.S. Application Data
(63) Continuation of application No. PCT/JP2022/046323, filed on Dec. 16, 2022.

(30) Foreign Application Priority Data
Jan. 17, 2022 (JP) 2022-005026

(51) Int. Cl. C23C 16/04; C23C 16/06; C23C 16/56; H01L 21/02

(52) U.S. Cl. CPC C23C 16/04; C23C 16/06; C23C 16/56; H01L 21/0228; H01L 21/02664

(57) ABSTRACT

An object of the present invention is to provide a chemical liquid for manufacturing a semiconductor, which is capable of forming an ALD film in a region targeted for ALD film formation and suppressing the formation of an ALD film in a region not targeted for ALD film formation, in a case where an ALD treatment is carried out after bringing the chemical liquid into contact with a predetermined substrate to form a modified film. Another object of the present invention is to provide a manufacturing method of a modified substrate using the above-mentioned chemical liquid, a manufacturing method of a laminate, and a chemical liquid container.

The chemical liquid for manufacturing a semiconductor of the present invention is a chemical liquid for manufacturing a semiconductor including a compound A having a specific functional group, an organic solvent, and a specific metal atom, in which a content of the compound A is more than 10 ppm by mass with respect to a total mass of the chemical liquid, a total content of the specific metal atom is 1,000 ppt by mass or less with respect to the total mass of the chemical liquid, a mass ratio of the content of the compound A to the content of the specific metal atom is 10⁴ to 10⁹, and a content of water contained in the chemical liquid is 1% by mass or less.

### CROSS-REFERENCE TO RELATED APPLICATIONS

This application is a Continuation of PCT International Application No. PCT/JP2022/046323 filed on Dec. 16, 2022, which claims priority under 35 U.S.C. § 119 (a) to Japanese Patent Application No. 2022-005026 filed on Jan. 17, 2022. The above applications are hereby expressly incorporated by reference, in their entirety, into the present application.

### BACKGROUND OF THE INVENTION

### 1. Field of the Invention

The present invention relates to a chemical liquid, a manufacturing method of a modified substrate, a manufacturing method of a laminate, and a chemical liquid container.

### 2. Description of the Related Art

With the further miniaturization of semiconductor devices, there is a demand for the formation of finer and more precise semiconductor elements. In the related art, photolithography has been used in the formation of a semiconductor element, but it requires registration of patterns or the like, and is no longer able to meet the accuracy required these days.

Accordingly, as a method for forming a semiconductor element, there is known a method in which, utilizing the properties of a compound that selectively adsorbs to a region formed of a specific material, a film consisting of such a compound is selectively formed, and the film is used to treat a region other than the region where the film is formed.

For example, JP2020-019899A discloses a technique for selectively forming a film by using a composition used for surface modification of a metal substrate, which contains a polymer having a first structural unit containing an aromatic ring and a second structural unit containing an ethylenic double bond, a thermal acid generator, and a solvent.

### SUMMARY OF THE INVENTION

A method for forming a fine pattern has been studied in which, for a substrate having a plurality of regions (for example, a metal region containing metal atoms and an insulating region containing an insulator) consisting of different materials on a surface thereof, one region is modified to form a film as described above, and then a treatment by atomic layer deposition (ALD) is carried out, whereby an ALD film is not formed in a region where a modified film is formed, and an ALD film is formed in a region where the modified film is not formed.

With reference to the technique described in JP2020-019899A, the present inventors have studied a method for manufacturing a modified substrate by forming a modified film on a substrate having a plurality of regions consisting of different materials, and then found that there is room for further improvement in order to form a modified substrate in which the formation of a modified film is suppressed through subsequent ALD treatment, whereby an ALD film is formed in a region where the ALD film is desired to be formed, and the formation of an ALD film is suppressed in a region where the modified film is formed and the ALD film is not desired to be formed.

Accordingly, an object of the present invention is to provide a chemical liquid for manufacturing a semiconductor, which is capable of forming an ALD film in a region targeted for ALD film formation and suppressing the formation of an ALD film in a region not targeted for ALD film formation, in a case where an ALD treatment is carried out after bringing the chemical liquid into contact with a predetermined substrate to form a modified film.

Another object of the present invention is to provide a manufacturing method of a modified substrate using the above-mentioned chemical liquid, a manufacturing method of a laminate, and a chemical liquid container.

As a result of extensive studies to achieve the foregoing objects, the present inventors have completed the present invention. That is, the present inventors have found that the foregoing objects can be achieved by the following configurations.

A chemical liquid for manufacturing a semiconductor, comprising a compound A having at least one functional group selected from the group consisting of a nitrogen-containing group, a phosphate group, a phosphonate group, a sulfo group, a carboxy group, a thiol group, and a hydroxy group; an organic solvent; and at least one specific metal atom selected from the group consisting of Cu and Fe, in which, in a case where the compound A has a hydroxy group, the compound A has a specific group which will be described later, a content of the compound A is more than 10 ppm by mass with respect to a total mass of the chemical liquid, a total content of the specific metal atom is 1,000 ppt by mass or less with respect to the total mass of the chemical liquid, a mass ratio of the content of the compound A to the total content of the specific metal atom is 10⁴ to 10⁹, and a content of water contained in the chemical liquid is 1% by mass or less.

The chemical liquid according to [1], in which the compound A has a molecular weight of 600 or less.

The chemical liquid according to [1] or [2], in which the compound A has an alkyl group having 8 or more carbon atoms which may have a substituent.

The chemical liquid according to any one of [1] to [3], in which the compound A has an alkyl group having 12 or more carbon atoms which may have a substituent.

The chemical liquid according to any one of [1] to [4], in which the compound A is a compound represented by Formula (1) which will be described later.

The chemical liquid according to [1], in which the compound A is a high-molecular-weight compound.

The chemical liquid according to any one of [1] to [6], in which the content of the compound A is 0.01% to 10% by mass with respect to the total mass of the chemical liquid.

The chemical liquid according to any one of [1] to [7], in which the mass ratio of the content of the compound A to the total content of the specific metal atom is 10⁵ to 10⁸.

The chemical liquid according to any one of [1] to [8], in which the chemical liquid is used for treating a semiconductor substrate having a plurality of regions consisting of different materials on a surface thereof.

The chemical liquid according to [9], in which the semiconductor substrate is a semiconductor substrate having a metal region containing tungsten, ruthenium, or molybdenum and an insulating region containing a silicon oxide or a silicon nitride on the surface thereof.

A manufacturing method of a modified substrate, comprising a step A of bringing the chemical liquid according to any one of [1] to [9] into contact with a substrate having a plurality of regions consisting of different materials on a surface thereof to form a coating film on at least one region of the plurality of regions.

The manufacturing method of a modified substrate according to [11], in which the substrate is a substrate having an insulating region containing silicon atoms and a metal region containing metal atoms on the surface thereof, and the coating film is formed on the metal region by the step A.

The manufacturing method of a modified substrate according to or [12], in which the step A is a step of bringing the chemical liquid into contact with the substrate to form the coating film, and the manufacturing method further comprises a step B of heating the coating film formed in the step A and a step C of subjecting the coating film heated in the step B to a rinsing treatment.

A manufacturing method of a laminate, comprising a step of forming a metal film containing metal atoms by atomic layer deposition on a region of a surface of a modified substrate manufactured by the manufacturing method according to any one of to [13], the region being different from a region on which a coating film is formed.

The manufacturing method of a laminate according to [14], further comprising a step of removing the coating film from the laminate on which the metal film is formed.

A chemical liquid container comprising a container; and the chemical liquid according to [1] to that is accommodated in the container.

The chemical liquid container according to [16], in which at least a part of an interior wall of the container is formed of a material selected from the group consisting of high density polyethylene, polypropylene, perfluoroalkoxyalkane, polytetrafluoroethylene, and stainless steel.

According to the present invention, it is possible to provide a chemical liquid for manufacturing a semiconductor, which is capable of forming an ALD film in a region targeted for ALD film formation and suppressing the formation of an ALD film in a region not targeted for ALD film formation, in a case where an ALD treatment is carried out after bringing the chemical liquid into contact with a predetermined substrate to form a modified film.

In addition, according to the present invention, it is also possible to provide a manufacturing method of a modified substrate using the above-mentioned chemical liquid, a manufacturing method of a laminate, and a chemical liquid container.

### DESCRIPTION OF THE PREFERRED EMBODIMENTS

Hereinafter, the present invention will be described in more detail.

The description of the configuration requirements described below is a representative embodiment of the present invention, and the present invention is not limited to such an embodiment.

Hereinafter, the meaning of each description in the present specification will be shown.

Any numerical range expressed using “to” in the present specification refers to a range including the numerical values before and after the “to” as a lower limit value and an upper limit value, respectively.

“ppm” in the present specification is an abbreviation for “parts per million” and means 10-6. In addition, “ppb” is an abbreviation for “parts per billion” and means 10-9. “ppt” is an abbreviation for “parts per trillion” and means 10-12.

In the present specification, in a case where two or more types of a certain component are present, the “content” of the component means a total content of the two or more types of components.

Unless otherwise specified, the “exposure” includes exposure with a mercury lamp, a far ultraviolet ray represented by an excimer laser, an X-ray, or EUV light, and drawing with a corpuscular beam such as an electron beam or an ion beam.

The “preparation” includes not only providing a specific material by synthesis, formulation, or the like, but also procuring a predetermined item by purchase or the like. [Chemical Liquid]

The chemical liquid according to an embodiment of the present invention (hereinafter, also simply referred to as a “chemical liquid”) is a chemical liquid for manufacturing a semiconductor, including a compound having a specific functional group which will be described later (hereinafter, also referred to as a “compound A”); an organic solvent; and at least one specific metal atom selected from the group consisting of Cu and Fe, in which a content of the compound A is more than 10 ppm by mass with respect to a total mass of the chemical liquid, a total content of the specific metal atom is 1,000 ppt by mass or less with respect to the total mass of the chemical liquid, a mass ratio of the content of the compound A to the total content of the specific metal atom is 10⁴ to 10⁹, and a content of water contained in the chemical liquid is 1% by mass or less.

Although the mechanism by which, in a case where the chemical liquid according to the embodiment of the present invention is brought into contact with a predetermined substrate to form a modified film and then an ALD treatment is carried out, an ALD film can be formed in a region targeted for ALD film formation and the formation of an ALD film can be suppressed in a region not targeted for ALD film formation is not necessarily clear, the present inventors speculate as follows.

By bringing the chemical liquid according to the embodiment of the present invention into contact with a substrate having a plurality of regions consisting of different materials on a surface thereof, a modified film containing the compound A having a specific functional group is formed in a modification target region consisting of a specific material (for example, a metal region containing metal atoms). At this time, it is considered that, in a case where the content of the compound A is 10 ppm by mass or less with respect to the total mass of the chemical liquid, a sufficient modified film will not be formed, and an ALD film will be formed in a non-target region. In addition, it is considered that, in a case where the content of water contained in the chemical liquid is more than 1% by mass, the water inhibits the formation of the modified film, resulting in the formation of the ALD film in the non-target region. Furthermore, it is considered that, in a case where the total content of the specific metal atom is more than 1,000 ppt by mass or in a case where the ratio of the content of the compound A to the total content of the specific metal atom is less than 10⁴, an ALD film in which a precursor is partial is formed at the time of the ALD treatment in a non-target region using the specific metal atom attached to the modified film as a nucleus. In addition, it is considered that, in a case where the ratio of the content of the compound A to the total content of the specific metal atom is more than 10⁹, surface asperities of the modified film to be formed are further increased, and the precursor of the ALD film is adsorbed to the surface asperities, resulting in the formation of a partial ALD film in the non-target region.

Hereinafter, the effect that is capable of forming an ALD film in a region targeted for ALD film formation and suppressing the formation of an ALD film in a region not targeted for ALD film formation, in a case where the ALD treatment is carried out after bringing the chemical liquid into contact with a predetermined substrate to form a modified film, will also be referred to as “the effect of the present invention”. [Composition of chemical liquid]

Hereinafter, the components that can be contained in the chemical liquid will be described.

### <Compound A>

The chemical liquid contains a compound A having at least one functional group selected from the group consisting of a nitrogen-containing group, a phosphate group (—PO₄H₂), a phosphonate group (—PO₃H₂), a sulfo group, a carboxy group (—COOH), a thiol group (—SH), and a hydroxy group (—OH) (hereinafter, also referred to as a “specific functional group”).

Here, the compound A having a hydroxy group as the specific functional group further has at least one group selected from the group consisting of specific functional groups (a nitrogen-containing group, a phosphate group, a phosphonate group, a sulfo group, a carboxy group, and a thiol group) other than the hydroxy group, and an alkyl group having 8 or more carbon atoms which may have a substituent. That is, compounds having a hydroxy group and neither a specific functional group other than the hydroxy group nor an alkyl group having 8 or more carbon atoms which may have a substituent are not included in the compound A.

A modified film containing the compound A is formed by the interaction of the specific functional group with atoms on the surface of a modification target region (for example, a metal region containing metal atoms) formed on the substrate.

It is noted that the specific functional group contained in the compound A may form a salt with a counterion or another group within the molecule. In the present specification, the compound A also includes an aspect in which the specific functional group forms a salt.

### (Specific Functional Group)

Examples of the nitrogen-containing group include a primary amino group (—NH₂), a secondary amino group (—NRTH), a tertiary amino group (—NR^{T}₂), a quaternary ammonium group (—N⁺R^{T}₃), a nitrogen-containing heterocyclic group, and salts thereof. A plurality of R^{T}'s of the tertiary amino group and the quaternary ammonium group may be the same as or different from each other.

R^{T} in the secondary amino group, the tertiary amino group, and the quaternary ammonium group represents an alkyl group which may have a substituent. The alkyl group represented by R^{T} is preferably an alkyl group having 1 to 5 carbon atoms, and more preferably an alkyl group having 1 to 3 carbon atoms. Examples of the substituent that the alkyl group may have include specific functional groups, among which a sulfo group or a carboxy group is preferable.

Examples of the nitrogen-containing heterocyclic group include nitrogen-containing heterocyclic groups having no aromaticity such as a pyrrolidine ring and a piperidine ring, and nitrogen-containing heteroaryl groups. The nitrogen-containing heteroaryl group may be monocyclic or polycyclic. Examples of the nitrogen-containing heteroaryl group include a pyridyl group, a bipyridyl group, a triazine group, a pyrrolyl group, a pyrazolyl group, an imidazolyl group, a triazolyl group, a benzimidazolyl group, and a benztriazolyl group.

The nitrogen-containing heterocyclic group is preferably a nitrogen-containing heteroaryl group, more preferably a pyridyl group, a bipyridyl group, or an imidazolyl group, and still more preferably a pyridyl group or a bipyridyl group.

The nitrogen-containing heterocyclic group may have a substituent. Examples of the substituent include an alkyl group, an aryl group (for example, a phenyl group), a halogen atom, a specific functional group, and a combination thereof. Above all, the substituent that the nitrogen-containing heterocyclic group has is preferably an alkyl group, a nitrogen-containing heterocyclic group, or a combination thereof. Examples of the alkyl group include the alkyl group that the compound A, which will be described later, may have, including a preferred aspect thereof.

Examples of salts of the primary amino group, the secondary amino group, the tertiary amino group, the quaternary ammonium group, and the nitrogen-containing heterocyclic group include salts with inorganic acids or organic acids in which at least one nonmetal selected from the group consisting of Cl, S, N, and P is bonded to hydrogen, among which a hydrochloride, a sulfate, or an acetate is preferable. In addition, an aspect in which a salt is formed in the molecule with the sulfo group or carboxy group that the compound A has is also preferable.

The phosphate group may form a salt with a counterion. The salt of the phosphate group refers to a group represented by —PO₄²⁻Ctⁿ⁺_{2/n}. Ctⁿ⁺ represents an n-valent cation, where n represents 1 or 2. Examples of the monovalent cation include Li⁺, Na⁺, K⁺, and NH₄⁺. In a case where Ct represents a monovalent cation, the number thereof is 2. Examples of the divalent cation include Mg⁺ and Ca⁺. In a case where Ct represents a divalent cation, the number thereof is 1. In addition, the phosphate group may form a salt in the molecule with the nitrogen-containing group that the compound A has.

Hereinafter, the compound having a phosphate group is also referred to as a “phosphate compound”.

The phosphonate group may form a salt with a counterion. The salt of the phosphonate group refers to a group represented by —PO₃²⁻Ctⁿ⁺_{2/n}. Ctⁿ⁺ represents an n-valent cation, where n represents 1 or 2. Examples of the monovalent cation and the divalent cation include the same cations as mentioned above, and the numbers thereof are also the same. In addition, the phosphonate group may form a salt in the molecule with the nitrogen-containing group that the compound A has.

Hereinafter, the compound having a phosphonate group is also referred to as a “phosphonate compound”.

The sulfo group may form a salt with a counterion. The salt of the sulfo group refers to a group represented by —SO₃⁻Ct⁺. Ct⁺ represents a monovalent cation, examples of which include the same cations as the above-mentioned monovalent cations. In addition, the sulfo group may form a salt in the molecule with the nitrogen-containing group that the compound A has.

The carboxy group may form a salt with a counterion. The salt of the carboxy group refers to a group represented by —COO⁻Ct⁺. Ct represents a monovalent cation, examples of which include the same cations as the above-mentioned monovalent cations. In addition, the carboxy group may form a salt in the molecule with the nitrogen-containing group that the compound A has.

From the viewpoint that adsorption properties to a substrate are more excellent, the specific functional group is preferably a group selected from the group consisting of a primary amino group or a salt thereof, a quaternary ammonium group or a salt thereof, a phosphate group or a salt thereof, a phosphonate group or a salt thereof, a sulfo group or a salt thereof, a carboxy group or a salt thereof, a thiol group, and a hydroxy group, and more preferably a primary amino group, a phosphonate group or a salt thereof, a carboxy group or a salt thereof, or a thiol group.

The number of specific functional groups that the compound A has is preferably 1 to 4, more preferably 1 or 2, and still more preferably 1.

The specific functional group that the compound A has is preferably bonded to a terminal of a hydrocarbon group which will be described later.

### (Hydrocarbon Group)

The compound A preferably has a hydrocarbon group which may have a substituent.

Examples of the substituent that the hydrocarbon group has include a specific functional group and a halogen atom. In addition, the hydrocarbon group which may have a substituent may have an ether group (—O—) instead of a methylene group (—CH₂−).

The hydrocarbon group which may have a substituent is preferably at least one group selected from the group consisting of an alkyl group, a polyoxyalkylene group, an aryl group (for example, a phenyl group), and a combination thereof, each of which may have at least one substituent selected from the group consisting of a specific functional group and a halogen atom.

In addition, it is preferable that the hydrocarbon group has a linear structure. The linear structure means that it does not have a branched structure having carbon atoms.

The number of carbon atoms in the hydrocarbon group which may have a substituent is preferably 8 or more, more preferably 12 or more, and still more preferably 14 or more. The upper limit of the number of carbon atoms in the hydrocarbon group is not particularly limited, and is preferably 20 or less.

Above all, the compound A preferably has an alkyl group which may have a substituent, and more preferably a linear alkyl group which may have a substituent. The number of carbon atoms in these alkyl groups is preferably 8 or more, more preferably 12 or more, and still more preferably 14 or more. The upper limit of the number of carbon atoms in these alkyl groups is not particularly limited, and is preferably 20 or less. The substituent that the alkyl group may have is the same as the substituent that the above-mentioned hydrocarbon group may have, including a preferred aspect thereof.

Examples of the linear alkyl group that the compound A may have include an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, and an icosyl group, among which an alkyl group having the above-mentioned number of carbon atoms is preferable.

Examples of the compound A having a linear alkyl group include a linear alkyl primary amine compound, a linear alkyl nitrogen-containing heterocyclic compound, a linear alkyl phosphate compound, a linear alkyl phosphonate compound, a linear alkyl sulfonic acid compound, a linear alkyl carboxylic acid compound, a linear alkyl thiol compound, a hydroxy linear alkyl thiol compound, and a linear alkyl alcohol compound.

The compound A is preferably a compound represented by Formula (1).

X-L-Y (1)

In the formula, X represents the above-mentioned specific functional group.

L represents a single bond or a divalent linking group.

Y represents an alkyl group which may have a substituent.

In a case where X represents a hydroxy group, Y represents an alkyl group having 8 or more carbon atoms which may have a substituent.

The specific functional group represented by X is the same as the specific functional group that the compound A has, including a preferred aspect thereof.

Above all, X is preferably a primary amino group, a quaternary amino group having an alkyl group having 1 to 5 carbon atoms which may have a substituent, a nitrogen-containing heterocyclic group which may have a linear alkyl group, a phosphate group, a phosphonate group, a sulfo group, a carboxy group, a thiol group, or a hydroxy group, and more preferably a primary amino group, a quaternary amino group having an alkyl group having 1 to 3 carbon atoms which may have a sulfo group, a nitrogen-containing heterocyclic group having a linear alkyl group, a phosphonate group, a sulfo group, a carboxy group, a thiol group, or a hydroxy group.

Examples of the divalent linking group include an ether group, a carbonyl group, an ester group, a thioether group, —SO₂—, and an arylene group, as well as a group formed by combination of these groups and an alkylene group. The divalent linking group may further have a substituent. Examples of the substituent include a specific functional group, an alkyl group, and a halogen atom.

L is preferably a single bond.

The alkyl group which may have a substituent, which is represented by Y, is the same as the alkyl group which may have a substituent that the compound A may have, including a preferred aspect thereof.

The compound A may be a low-molecular-weight compound or a high-molecular-weight compound.

In the present specification, the low-molecular-weight compound refers to a compound having a molecular weight (a weight-average molecular weight in a case of having a molecular weight distribution) of 1,000 or less, and the high-molecular-weight compound refers to a compound having a molecular weight (a weight-average molecular weight in a case of having a molecular weight distribution) of more than 1,000.

The compound A is preferably a low-molecular-weight compound from the viewpoint that the adsorption selectivity to each substrate is more excellent.

In a case where the compound A is a low-molecular-weight compound, the molecular weight thereof (the weight-average molecular weight in a case of having a molecular weight distribution) is preferably 600 or less and more preferably 300 or less. The molecular weight of the low-molecular-weight compound is preferably 60 or more.

In a case where the compound A is a high-molecular-weight compound, the molecular weight thereof (the weight-average molecular weight in a case of having a molecular weight distribution) is preferably more than 1,000 and 100,000 or less and more preferably more than 1,000 and 10,000 or less.

Examples of the compound A which is a high-molecular-weight compound include a polymer having at least one specific functional group and at least one main chain selected from the group consisting of a polyoxyalkylene chain and a polyethylene chain. The specific functional group may be directly bonded to the main chain or may be bonded to a side chain.

The chemical liquid may contain one type of compound A or a plurality of types of compounds A.

In a case where the chemical liquid contains a plurality of types of compounds A, the content of any one type of compounds A is preferably 10% to 90% by mass and more preferably 20% to 80% by mass with respect to the total content of compounds A.

As described above, the content of the compound A is more than 10 ppm by mass with respect to the total mass of the chemical liquid.

From the viewpoint that the effect of the present invention is more excellent, the content of the compound A is preferably 0.01% to 10.0% by mass, more preferably 0.1% to 5.0% by mass, and still more preferably 0.5% to 3.0% by mass with respect to the total mass of the chemical liquid.

### <Organic Solvent>

The chemical liquid contains an organic solvent. In this regard, a compound corresponding to the compound A is not included in the organic solvent.

The organic solvent is a liquid organic compound under a condition of 25° C.

The organic solvent is preferably a polar organic solvent that is dissolved in an amount of 0.1 g or more in 100 g of water under a condition of 25° C., and is more preferably a polar organic solvent that is miscible with water in any ratio.

Examples of the organic solvent include a hydrocarbon-based solvent, an alcohol-based solvent, a glycol-based solvent, a glycol ether-based solvent, a ketone-based solvent, and a sulfur-containing solvent.

In the present specification, any of a compound having a hydroxy group and a specific functional group other than the hydroxy group and a compound having a hydroxy group and an alkyl group having 8 or more carbon atoms which may have a substituent are not included in the alcohol-based solvent, glycol-based solvent, and glycol ether-based solvent.

Examples of the hydrocarbon-based solvent include n-pentane, n-hexane, cyclohexane, methylcyclohexane, toluene, and xylene.

Examples of the alcohol-based solvent include a saturated aliphatic monohydric alcohol, an unsaturated non-aromatic monohydric alcohol, an alcohol containing a ring structure, an alkanediol, and an alkoxyalcohol.

The number of carbon atoms in the alcohol-based solvent is preferably 1 to 7, more preferably 2 to 7, and still more preferably 3 to 6.

Examples of the saturated aliphatic monohydric alcohol include methanol, ethanol, n-propyl alcohol, isopropanol (isopropyl alcohol, IPA), 1-butanol, 2-butanol, isobutyl alcohol, tert-butyl alcohol, 2-pentanol, t-pentyl alcohol, 1-hexanol, and 4-methyl-2-pentanol (MIBC).

Examples of the unsaturated non-aromatic monohydric alcohol include allyl alcohol, propargyl alcohol, 2-butenyl alcohol, 3-butenyl alcohol, and 4-penten-2-ol.

Examples of the alcohol containing a ring structure include tetrahydrofurfuryl alcohol, furfuryl alcohol, and 1,3-cyclopentanediol.

Examples of the alkanediol include 2-methyl-1,3-propanediol, 1,3-propanediol, 2,2-dimethyl-1,3-propanediol, 1,4-butanediol, 1,3-butanediol, 1,2-butanediol, 2,3-butanediol, and pinacol.

Examples of the alkoxy alcohol include 3-methoxy-3-methyl-1-butanol, 3-methoxy-1-butanol, and 1-methoxy-2-butanol.

Examples of the glycol-based solvent include ethylene glycol, propylene glycol, diethylene glycol, dipropylene glycol, triethylene glycol, and tetraethylene glycol.

Examples of the glycol ether-based solvent include glycol monoether.

Examples of the glycol monoether include ethylene glycol monomethyl ether, ethylene glycol monoethyl ether, ethylene glycol mono-n-propyl ether, ethylene glycol monoisopropyl ether, ethylene glycol mono-n-butyl ether, diethylene glycol monomethyl ether, diethylene glycol monoethyl ether, diethylene glycol monobutyl ether, triethylene glycol monomethyl ether, triethylene glycol monoethyl ether, triethylene glycol monobutyl ether, 1-methoxy-2-propanol, 2-methoxy-1-propanol, 1-ethoxy-2-propanol, 2-ethoxy-1-propanol, propylene glycol mono-n-propyl ether, dipropylene glycol monomethyl ether, dipropylene glycol monoethyl ether, dipropylene glycol mono-n-propyl ether, tripropylene glycol monoethyl ether, tripropylene glycol monomethyl ether, ethylene glycol monobenzyl ether, and diethylene glycol monobenzyl ether.

Examples of the ketone-based solvent include acetone, methyl ethyl ketone, methyl isobutyl ketone, and cyclohexanone.

Examples of the sulfur-containing solvent include dimethyl sulfone, dimethyl sulfoxide, and sulfolane.

The organic solvent is preferably an alcohol-based solvent, a glycol ether-based solvent, or a ketone-based solvent, more preferably an alcohol-based solvent, and still more preferably 4-methyl-2-pentanol (MIBC) or isopropanol (IPA).

One type of organic solvent may be used alone, or two or more types of organic solvents may be used in combination. Above all, from the viewpoint that the effect of the present invention is more excellent, it is preferable that the chemical liquid contains two or more types of organic solvents. In a case where the chemical liquid contains two or more types of organic solvents, the number of types of organic solvents is preferably 2 to 4 and more preferably 2.

In a case where the chemical liquid contains two or more types of organic solvents, it is preferable that the chemical liquid contains at least one type of alcohol-based solvent.

The content of the organic solvent is not particularly limited, and is preferably 90% to 99.99% by mass, more preferably 95% to 99.9% by mass, and still more preferably 97% to 99.5% by mass with respect to the total mass of the chemical liquid.

In a case where a plurality of organic solvents are used in combination, a mixing ratio of the organic solvents is not particularly limited. In a case where the chemical liquid contains two types of organic solvents, that is, a first organic solvent and a second organic solvent, a mass ratio of the second organic solvent to the first organic solvent is preferably 0.1 to 10 and more preferably 0.3 to 3.3.

### <Specific Metal Atom>

The chemical liquid according to the embodiment of the present invention contains at least one specific metal atom selected from the group consisting of Cu and Fe, and the total content of the specific metal atom is 1,000 ppt by mass (1 ppm by mass) or less with respect to the total mass of the chemical liquid.

The form of the specific metal atom in the chemical liquid is not particularly limited, and the specific metal atom may be a metal particle containing a simple substance of specific metal atom or may be a metal ion. The metal particle may contain only a specific metal atom, or may be an alloy containing a simple substance of specific metal atom.

The specific metal atom may be any of a metal atom derived from a metal component that is unavoidably contained in each component (raw material) contained in the chemical liquid, a metal atom derived from a metal component that is unavoidably contained in one or more steps selected from the group consisting of manufacturing, storage, and transportation of the chemical liquid, and a metal atom derived from a metal component that is intentionally added.

The lower limit value of the total content of the specific metal atom is not particularly limited. The total content of the specific metal atom may be, for example, 0.001 ppt by mass or more with respect to the total mass of the chemical liquid.

In the chemical liquid according to the embodiment of the present invention, the mass ratio of the content of the compound A to the total content of the specific metal atom is 10⁴ to 10⁹. From the viewpoint that the effect of the present invention is more excellent, particularly from the viewpoint that an ability to inhibit the formation of an aluminum oxide film is more excellent, the mass ratio of the content of the compound A to the total content of the specific metal atom is preferably 10⁵ to 10⁸ and more preferably 10⁵ to 107.

The type and content of the specific metal atom can be measured by inductively coupled plasma mass spectrometry (ICP-MS). With ICP-MS, the content of the specific metal atom as a measurement target is measured regardless of the way the specific metal atom is present. Accordingly, the total mass of metal particles and metal ions of the specific metal atom that is a measurement target is quantified as the content of the specific metal atom.

Examples of a method of adjusting the content of the specific metal atom include a method of carrying out a known treatment of removing the specific metal atom from a chemical liquid and/or a raw material containing each component used in the preparation of a chemical liquid, and a method of adding a compound containing a metal ion of the specific metal atom to a chemical liquid. Examples of the treatment for removing the specific metal atom include a metal removal step which will be described later.

The chemical liquid may contain other metal atoms in addition to the specific metal atom.

Examples of those other metal atoms include a transition metal atom other than the specific metal atom.

### <Water>

The content of water contained in the chemical liquid according to the embodiment of the present invention is 1% by mass or less.

In the present specification, the phrase “the content of water contained in the chemical liquid is 1% by mass or less” means that the chemical liquid may contain water or may not contain water, but in a case where the chemical liquid contains water, the content of water is 1% by mass or less with respect to the total mass of the chemical liquid.

In addition, in the present specification, the phrase “chemical liquid does not contain water” means that the content of water measured by a measuring method which will be described later is 0.5% by mass or less with respect to the total mass of the chemical liquid.

In a case where the chemical liquid contains water, the water is preferably water that has been subjected to a purification treatment, such as distilled water, ion exchange water, and ultrapure water, and more preferably ultrapure water used for manufacturing semiconductors. The water contained in the chemical liquid may contain trace amounts of components that are unavoidably mixed in.

From the viewpoint that the effect of the present invention is more excellent, the content of water is preferably 1% by mass or less and more preferably 0.5% by mass or less with respect to the total mass of the chemical liquid. Above all, it is still more preferable that the chemical liquid does not contain water.

The content of water contained in the chemical liquid refers to a content of water measured using a device based on a Karl Fischer moisture measurement method as the principle of measurement.

### <Other Components>

The chemical liquid according to the embodiment of the present invention may contain other components in addition to the components described above.

Examples of other components include a polymer not included in the compound A. Examples of the polymer include an acrylic polymer, a siloxane-based polymer, and a styrene-based polymer.

### [Manufacturing Method of Chemical Liquid]

The manufacturing method of the chemical liquid is not particularly limited, and the chemical liquid can be manufactured, for example, by mixing the above-mentioned components. The order and timing of mixing the above-mentioned components are not particularly limited. For example, a method of manufacturing a chemical liquid by adding the compound A to a stirrer such as a mixing mixer containing a purified organic solvent, and then sufficiently stirring the mixture can be mentioned.

In the manufacturing process of the chemical liquid, the steps described below may be carried out.

### <Filtration Step>

It is preferable that the above-mentioned manufacturing method includes a filtration step of filtering the above-mentioned components and/or chemical liquid (hereinafter, also referred to as “substance to be purified”) in order to remove foreign substances, coarse particles, and the like from the liquid.

The filtration method is not particularly limited, and a known filtration method can be used. Above all, filtering using a filter is preferable.

Any filter that is used for filtering can be used without particular limitation, as long as it is a filter that has been used in the related art for filtration or the like. Examples of the material constituting the filter include a fluororesin such as polytetrafluoroethylene (PTFE), a polyamide-based resin such as nylon, a polyolefin-based resin (including a high density, ultrahigh-molecular-weight polyolefin-based resin) such as polyethylene or polypropylene (PP), and polyarylsulfone. Above all, a polyamide-based resin, PTFE, polypropylene (including high density polypropylene), and polyarylsulfone are preferable.

The lower limit value of the critical surface tension of the filter is preferably 70 mN/m or more, and the upper limit value of the critical surface tension of the filter is preferably 95 mN/m or less. In particular, the critical surface tension of the filter is preferably 75 to 85 mN/m. It is noted that the value of the critical surface tension is a nominal value of a manufacturer.

The pore diameter of the filter is preferably about 0.001 to 1.0 μm, more preferably about 0.02 to 0.5 μm, and still more preferably about 0.01 to 0.1 μm. In a case where the pore diameter of the filter is in the above range, it is possible to reliably remove fine foreign substances contained in the substance to be purified while suppressing filter clogging.

In a case of using the filter, different filters may be combined. At this time, filtering using a first filter may be carried out only once, or may be carried out two or more times. In a case where filtering is carried out two or more times by combining different filters, the filters may be of the same type or different types, but it is preferable that the filters are of different types. Typically, it is preferable that the first filter and the second filter differ from each other in at least one of the pore diameter or the constituent material.

It is preferable that the pore diameters in the second filtering and the subsequent filtering are equal to or smaller than the pore diameter in the first filtering. In addition, the first filters having different pore diameters within the above range may be combined. With regard to the pore diameter of the filter herein, reference can be made to a nominal value of the filter manufacturer.

### <Metal Removal Step>

In the above manufacturing method, a metal removal step of removing a metal component from a substance to be purified may be carried out.

Examples of the metal removal step include a step P in which the substance to be purified is subjected to an ion exchange method.

### (Step P)

In the step P, the above-mentioned substance to be purified is subjected to an ion exchange method.

The ion exchange method is not particularly limited as long as it is a method that can adjust (reduce) the amount of metal components in the substance to be purified. From the viewpoint of more easily manufacturing the chemical liquid, the ion exchange method preferably includes one or more of the following methods P1 to P3. The ion exchange method more preferably includes two or more of the methods P1 to P3, and still more preferably includes all of the methods P1 to P3. In a case where the ion exchange method includes all of the methods P1 to P3, the methods may be carried out in any order without particular limitation, but it is preferable to carry out the methods P1 to P3 in this order.

Method P1: a method of passing the substance to be purified through a first filling portion filled with a mixed resin including two or more resins selected from the group consisting of a cation exchange resin, an anion exchange resin, and a chelating resin.

Method P2: a method of passing the substance to be purified through at least one filling portion of a second filling portion filled with a cation exchange resin, a third filling portion filled with an anion exchange resin, or a fourth filling portion filled with a chelating resin.

Method P3: a method of passing the substance to be purified through a membrane-like ion exchanger.

In a case where the ion exchange resins (the cation exchange resin and the anion exchange resin), the chelating resin, and the membrane-like ion exchanger used in each of the methods are in forms other than H′ form or OH form, it is preferable to use the resins and the ion exchanger after being regenerated into H′ form or OH-form.

In addition, the space velocity (SV) of the substance to be purified in each of the methods is preferably 0.01 to 20.0 (1/h) and more preferably 0.1 to 10.0 (1/h).

In addition, the treatment temperature in each of the methods is preferably 0° C. to 60° C. and more preferably 10° C. to 50° C.

In addition, examples of the form of the ion exchange resin and chelating resin include a granular form, a fibrous form, and a porous monolithic form, among which a granular form or a fibrous form is preferable.

The average particle diameter of the granular ion exchange resin and chelating resin is preferably 10 to 2,000 μm and more preferably 100 to 1,000 μm.

As for the particle size distribution of the granular ion exchange resin and chelating resin, it is preferable that the abundance ratio of resin particles having a size in a range of average particle diameter±200 μm is 90% or more.

The average particle diameter and the particle size distribution may be measured, for example, using a particle size distribution analyzer (Microtrac HRA3920, manufactured by Nikkiso Co., Ltd.) and using water as a dispersion medium.

The ion exchange method is preferably carried out until the content of the metal component contained in the substance to be purified falls into the above-mentioned preferred range of the metal component content.

### <Static Neutralization Step>

The manufacturing method of the chemical liquid may further include a static neutralization step of statically neutralizing the substance to be purified.

### [Chemical Liquid Container]

An embodiment of the present invention includes a chemical liquid container having a container and a chemical liquid accommodated in the container.

The chemical liquid is as described above.

Any known container can be used as the container for accommodating the chemical liquid. The container is preferably a container for semiconductor applications which has a high degree of internal cleanliness and has a low elution of impurities.

Examples of the container include “CLEAN BOTTLE” series (manufactured by Aicello Chemical Co., Ltd.) and “PURE BOTTLE” (manufactured by Kodama Plastics Co., Ltd.). In addition, from the viewpoint of preventing the incorporation of impurities (contamination) into the raw materials and the chemical liquid, it is also preferable to use a multi-layer container in which an interior wall of the container has a six-layer structure consisting of six types of resins, or a multi-layer container in which an interior wall of the container has a seven-layer structure consisting of seven types of resins.

Examples of the multi-layer container include the containers described in JP2015-123351A, the contents of which are incorporated herein by reference.

Examples of materials for the interior wall of the container include a first resin of at least one selected from the group consisting of a polyethylene resin, a polypropylene resin, and a polyethylene-polypropylene resin, a second resin different from the first resin, and a metal such as stainless steel, Hastelloy, Inconel, or Monel. In addition, it is preferable that at least a part of the interior wall (preferably all of the interior wall) of the container is formed of the above-mentioned material.

The second resin is preferably a fluororesin (perfluororesin). Examples of the fluororesin include perfluoroalkoxyalkane (PFA) and polytetrafluoroethylene (PTFE). In a case where a fluororesin is used, elution of an oligomer of ethylene or propylene can be suppressed.

Examples of the container having an interior wall formed of a fluororesin include a FluoroPure PFA composite drum (manufactured by Entegris, Inc.), and the containers described on page 4 of JP1991-502677A (JP-H-03-502677A), page 3 of WO2004/016526A, and pages 9 and 16 of WO99/046309A.

In addition to the fluororesin, for example, quartz and an electropolished metal material (a metal material subjected to electropolishing) are also preferable for the interior wall of the container.

The metal material used for the electropolished metal material is preferably a metal material containing at least one selected from the group consisting of chromium (Cr) and nickel (Ni), in which the total content of Cr and Ni is more than 25% by mass with respect to the total mass of the metal material. Examples of such a metal material include stainless steel (steel use stainless (SUS)) and an Ni—Cr alloy.

The total content of Cr and Ni in the metal material is preferably 25% by mass or more and more preferably 30% by mass or more with respect to the total mass of the metal material. The upper limit of the total content of Cr and Ni is preferably 90% by mass or less with respect to the total mass of the metal material.

Examples of the stainless steel (SUS) include known stainless steel. Above all, stainless steel containing 8% by mass or more of Ni is preferable, and austenitic stainless steel containing 8% by mass or more of Ni is more preferable.

Examples of the austenitic stainless steel include SUS304 (Ni content: 8% by mass, Cr content: 18% by mass), SUS304L (Ni content: 9% by mass, Cr content: 18% by mass), SUS316 (Ni content: 10% by mass, Cr content: 16% by mass), and SUS316L (Ni content: 12% by mass, Cr content: 16% by mass).

Examples of the Ni—Cr alloy include known Ni—Cr alloys. Above all, a Ni—Cr alloy having a Ni content of 40% to 75% by mass and a Cr content of 1% to 30% by mass is preferable. The Ni—Cr alloy may further contain boron, silicon, tungsten, molybdenum, copper, or cobalt in addition to the above-mentioned components, if necessary.

Examples of the method for electropolishing a metal material include known methods.

Specific examples of the method for electropolishing a metal material include the methods described in paragraphs to of JP2015-227501A, the contents of which are incorporated herein by reference and the methods described in paragraphs to of JP2008-264929A, the contents of which are incorporated herein by reference.

The metal material is preferably subjected to buffing. Examples of the buffing method include known methods. The size of abrasive grains used for finishing the buffing is preferably #400 or less from the viewpoint that surface asperities of the metal material are likely to be further reduced. The buffing is preferably carried out before the electropolishing.

The metal material may be subjected to one of multi-stage buffing that is carried out by changing the size or the like of the abrasive grains, acid washing, magnetorheological finishing, and the like, or a combination of two or more thereof.

From the viewpoint of suppressing contamination of the chemical liquid by eluates from the container, at least a portion of the interior wall (preferably the entire interior wall) of the container is preferably formed of at least one material selected from the group consisting of a polyethylene resin, a polypropylene resin, a polyethylene-polypropylene resin, a fluororesin, and stainless steel, and is more preferably formed of a material selected from the group consisting of high density polyethylene (HDPE), polypropylene (PP), perfluoroalkoxyalkane (PFA), polytetrafluoroethylene (PTFE), and stainless steel. In addition, from the viewpoint of the performance stability of the chemical liquid after long-term storage, it is preferable that at least a portion of the interior wall (preferably the entire interior wall) of the container is formed of a fluororesin such as PFA or PTFE.

It is preferable to clean the inside of the container before being filled with the chemical liquid.

The liquid used for cleaning can be appropriately selected depending on the intended use, and is preferably a liquid containing the chemical liquid or at least one of the components added to the chemical liquid.

The inside of the container may be purged with an inert gas (for example, nitrogen or argon) having a purity of 99.99995% by volume or higher from the viewpoint of preventing changes in the components of the chemical liquid during storage. In particular, a gas having a low moisture content is preferable. Transportation and storage of the container accommodating the chemical liquid may be carried out either at normal temperature (25° C.) or in a temperature-controlled environment. Above all, from the viewpoint of preventing deterioration, it is preferable that the transportation and storage are carried out in an environment with a temperature controlled in a range of −20° C. to 20° C.

### [Applications of Chemical Liquid]

The chemical liquid is used to treat a substrate (preferably a semiconductor substrate) having a plurality of regions consisting of different materials on a surface thereof. By treating the substrate having a plurality of regions on a surface thereof with the chemical liquid, a modified substrate in which a film containing the compound A (modified film) is formed on the surface of at least one of the plurality of regions is obtained.

The method for treating the substrate is not particularly limited, and the modified substrate is obtained by bringing the chemical liquid into contact with the substrate having a plurality of regions on a surface thereof. The manufacturing method of the modified substrate will be described later.

Examples of the region that can be formed on the surface of the substrate include a metal region containing metal atoms and an insulating region containing silicon atoms.

The metal region refers to a region whose surface is composed of a metal-containing substance. Examples of the metal-containing substance constituting the metal region include a simple substance of metal, a metal oxide, a metal nitride, and a metal oxynitride.

The type of metal contained in the metal region is not particularly limited, and is preferably a transition metal, more preferably a Group 6 to Group 11 element, still more preferably a Group 6 element, a Group 8 element, a Group 9 element, or a Group 11 element, and particularly preferably tungsten (W), ruthenium (Ru), or molybdenum (Mo). The metal-containing substance constituting the metal region may be an alloy containing the above-mentioned metal, an oxide of the above-mentioned metal, a nitride of the above-mentioned metal, or an oxynitride of the above-mentioned metal.

Examples of the material constituting the insulating region containing silicon atoms, which is formed on the surface of the substrate, include a silicon oxide (for example, silicon dioxide (SiO₂) or tetraethyl orthosilicate (Si(OC₂H₅)₄, TEOS)), a silicon nitride (for example, silicon nitride (Si₃N₄) or silicon nitride carbide (SiNC)), and a low-dielectric constant (Low-k) material (for example, carbon-doped silicon oxide (SiOC) or silicon carbide (SIC)).

The chemical liquid is preferably used for treating a substrate having a plurality of regions including the above-mentioned metal region on a surface thereof, is more preferably used for treating a substrate having a plurality of regions including the above-mentioned metal region and the above-mentioned insulating region on a surface thereof, and is still more preferably used for treating a substrate having a metal region containing W, Ru, or Mo and an insulating region containing a silicon oxide or a silicon nitride on a surface thereof.

### <Manufacturing Method of Modified Substrate>

An embodiment of the present invention includes a manufacturing method of a modified substrate which includes a step A of bringing a chemical liquid into contact with a substrate having a plurality of regions consisting of different materials on a surface thereof to form a coating film on at least one region of the plurality of regions.

Examples of the substrate having a plurality of regions consisting of different materials on a surface thereof include the substrates listed as targets for treatment using the above-mentioned chemical liquid, including a preferred aspect thereof.

In the manufacturing method of a modified substrate, it is preferable that the substrate is a substrate having an insulating region containing silicon atoms and a metal region containing metal atoms on a surface thereof, and the step A is a step of bringing the chemical liquid into contact with the substrate to form a coating film on the metal region.

The contact method is not particularly limited, and examples thereof include a method of applying or spraying the chemical liquid onto the surface of the substrate as a target and a method of immersing the substrate as a target in the chemical liquid. The method of applying the chemical liquid onto the substrate is not particularly limited, and any known method can be used, such as spin coating. In addition, in a case where the substrate is immersed in the chemical liquid, the chemical liquid may be subjected to convection. The temperature of the chemical liquid brought into contact with the substrate in the step A is not particularly limited, and is preferably 10° C. to 50° C.

It is preferable that the manufacturing method of a modified substrate includes, after the step A, a step B of heating the coating film formed in the step A. The organic solvent can be removed by heating, so that the coating film containing the compound A can be made denser.

The heating temperature is not particularly limited, and is preferably 50° C. to 300° C. and more preferably 60° C. to 180° C.

The heating method is not particularly limited, and examples thereof include a method of being brought into contact with a heating element (for example, heating with a hot plate) and a method of irradiation with infrared rays.

In addition, it is preferable that the manufacturing method of a modified substrate includes, after the step B, a step C of subjecting the coating film heated in the step B to a rinsing treatment. The compound A that has adhered to a region other than a desired region can be removed from the substrate by the rinsing treatment.

The rinsing method is not particularly limited, and examples thereof include a method of bringing a rinsing liquid into contact with the substrate. Examples of the contact method include the same method as the contact method in the step A above. The temperature of the rinsing liquid brought into contact with the substrate in the step C is not particularly limited, and is preferably 10° C. to 50° C.

The rinsing liquid is not particularly limited, and examples thereof include an organic solvent contained in a chemical liquid. The organic solvent contained in the chemical liquid used to form the coating film may be used as the rinsing liquid.

In the above-mentioned manufacturing method of a modified substrate, by using the chemical liquid according to the embodiment of the present invention, it is possible to manufacture a modified substrate that has a coating film containing the compound A on at least one region (for example, a metal region containing metal atoms) of a plurality of regions and does not have a coating film containing the compound A on the other region (an insulating region containing silicon atoms).

The coating film containing the compound A (hereinafter, also referred to as a “modified film”), which is included in the modified substrate manufactured by the above-mentioned method, has a suitable function as a mask in a case of forming a metal-containing film by atomic layer deposition (ALD) on the surface of the modified substrate on which the modified film is formed. In other words, it is preferable that a film by ALD (hereinafter, also referred to as an “ALD film”) is difficult to deposit in the region where the modified film is formed, and the ALD film is deposited in the region where the formation of the modified film is suppressed. Since the modified film functions as a mask in the formation of the ALD film, a laminate can be obtained in which the formation of the ALD film is suppressed in the region on the substrate where the modified film is formed, and the ALD film is selectively formed in a region other than the region where the modified film is formed. The manufacturing method of the laminate will be described later.

The contact angle of the modified film with respect to water is preferably 60° or more and more preferably 90° or more from the viewpoint that the modified film easily functions as a mask for ALD. The upper limit of the contact angle is not particularly limited and is preferably 110° or less.

### <Manufacturing Method of Laminate>

An embodiment of the present invention includes a manufacturing method of a laminate which includes a step of subjecting the modified substrate to an ALD treatment to form an ALD film on a region where the formation of a modified film is suppressed (for example, on a region other than the metal region).

The manufacturing method of a laminate is preferably a manufacturing method of a laminate which includes a step of forming a metal film containing metal atoms by ALD on an insulating region of a modified substrate including a substrate having an insulating region and a metal region, and a modified film formed on the metal region of the substrate, which is manufactured by the above-mentioned manufacturing method of a modified substrate.

By carrying out the ALD treatment on the modified substrate, a laminate can be obtained in which the formation of the ALD film is suppressed on the metal region where the modified film is formed, and the ALD film is selectively formed on the insulating region.

In the ALD treatment, a precursor serving as a raw material of the ALD film is supplied to the surface of the modified substrate. The material constituting the ALD film to be formed can be controlled by the type of precursor supplied, the supply atmosphere, the oxidant, and the like.

The material constituting the ALD film is not particularly limited as long as it is a material containing metal atoms, and examples thereof include a simple substance of metal, a metal oxide, and a metal nitride. Examples of the simple substance of metal include aluminum, titanium, chromium, iron, cobalt, nickel, copper, zinc, yttrium, zirconium, niobium, molybdenum, ruthenium, palladium, lanthanum, cerium, hafnium, tantalum, tungsten, platinum, and bismuth. Examples of the metal oxide include aluminum oxide, titanium oxide, zinc oxide, zirconium oxide, hafnium oxide, and tantalum oxide. Examples of the metal nitride include titanium nitride and tantalum nitride.

In the ALD treatment, a treatment to alter the surface of the region where the formation of the modified film is suppressed may be carried out.

In a case where an ALD film is selectively formed on the region where the formation of a modified film is suppressed by the ALD treatment, a ratio of the thickness of the ALD film on the region where the modified film is formed to the thickness of the ALD film on the region where the formation of the modified film is suppressed is preferably 0.75 or less, more preferably 0.5 or less, and still more preferably 0.25 or less. The lower limit of the ratio may be 0. That is, the ALD film may not be formed on the region where the modified film is formed.

The above-mentioned manufacturing method of a laminate may include, after carrying out the ALD treatment, a step of removing the modified film on the region where the modified film is formed (for example, the metal region). By removing the modified film in this step, a laminate in which the ALD film is formed only on a region other than the region where the modified film is formed (for example, an insulating region) can be obtained.

The method of removing the modified film is not particularly limited, and examples thereof include dry etching, wet etching, and a combination thereof.

Examples of the dry etching include a method of supplying reactive ions or reactive radicals to the surface of the laminate having a modified film. The reactive ions or the reactive radicals may be generated by plasma or the like, and are preferably generated using a mixed gas containing one or more gases selected from the group consisting of oxygen, nitrogen, and hydrogen. The mixed gas may contain a rare gas. In addition, the dry etching may be physical etching using a sputtering phenomenon.

Examples of the wet etching include a method of supplying an etchant to the surface of the laminate having a modified film. Examples of the etchant include an etchant containing an oxidant such as ozone and an etchant containing an organic solvent. Examples of the organic solvent in the etchant containing an organic solvent include the organic solvent contained in the above-mentioned chemical liquid, among which a hydrocarbon-based solvent is preferable.

The modified substrate preferably also functions as a mask in a case where a metal-containing film is formed by chemical vapor deposition (CVD) other than the ALD treatment. That is, in the CVD treatment, the deposition of a film by CVD (hereinafter, also referred to as a “CVD film”) is suppressed in the region where the modified film is formed, and the CVD film can be deposited in the region where the formation of the modified film is suppressed. Since the modified film functions as a mask in the formation of the CVD film in this manner, a laminate can be obtained in which the formation of the CVD film is suppressed in the region on the substrate where the modified film is formed, and the CVD film is selectively formed in a region other than the region where the modified film is formed.

Examples of the CVD other than the ALD, which can be preferably applied to the modified substrate, include known methods such as thermal CVD and plasma CVD. Examples of the raw material for the CVD film used in the CVD treatment include the materials listed as the raw materials for the ALD film described above.

### EXAMPLES

Hereinafter, the present invention will be described in more detail with reference to Examples.

The materials, amounts of materials used, proportions, treatment details, treatment procedure, and the like shown in Examples given below can be appropriately modified without departing from the spirit and scope of the present invention. Accordingly, the scope of the present invention should not be construed as being limited to Examples given below.

### [Preparation of Chemical Liquid]

For Example 1, octadecylamine hydrochloride (compound A-1) as the compound A was added to 4-methyl-2-pentanol (MIBC), which is an organic solvent, at a content shown in Table 1 to form a mixed solution, and then the mixed solution was sufficiently stirred with a stirrer to obtain a chemical liquid of Example 1.

The obtained chemical liquid was filled into a container made of high density polyethylene (HDPE) whose interior wall in contact with the chemical liquid was formed of HDPE to obtain a chemical liquid container.

The preparation, filling, storage, and the like of the chemical liquid were all carried out in a clean room satisfying a level equal to or lower than ISO Class 2. In addition, the container used for the preparation, filling, storage, and the like of the chemical liquid was used after being cleaned with the solvent used for the preparation or the prepared chemical liquid.

Chemical liquids of Examples 2 to 15 and chemical liquids of Comparative Examples 2 to 9 were prepared in the same manner as in Example 1, except that the type and amount of each component contained in the chemical liquid and the container accommodating the chemical liquid were changed according to Tables 1 to 3.

The contents of various components in each chemical liquid are as described in the tables. In this regard, the content of the organic solvent is the remainder of each component.

With regard to various components used in the preparation of the chemical liquid in each of Examples and each of Comparative Examples, components all classified into a semiconductor grade or components all classified into a high-purity grade equivalent to the semiconductor grade were used. In this regard, a compound C-1 which will be described later was manufactured according to a known method.

In addition, the concentrations of metal atoms of Cu and Fe in the chemical liquid were appropriately adjusted to the values shown in the tables. More specifically, the concentration of each metal atom was adjusted by subjecting the chemical liquid to the ion exchange treatment or filtration described as the metal removal step described above, and/or by preparing a solution in which metal ions containing each metal atom were dissolved in the chemical liquid or an organic solvent, further diluting the solution as necessary, and then adding the resulting solution to the chemical liquid.

### [Components]

Hereinafter, each component used in the preparation of each chemical liquid will be shown.

### <Compound A>

Compound A-1: octadecylamine hydrochloride
Compound A-2: octadecylamine
Compound A-3: octadecylamine acetate
Compound A-4: octadecyltrimethylammonium chloride
Compound A-5: octadecyldimethyl (3-sulfopropyl) ammonium hydroxide intramolecular salt
Compound A-6:4,4′-dinonyl-2,2′-bipyridyl
Compound A-7: octadecyl alcohol
Compound A-8: octadecylthiol
Compound A-9: stearic acid
Compound A-10: octadecylphosphonic acid

In Comparative Example 2, the following compound was used instead of the compound A.
Compound C-1: resin represented by the following formula

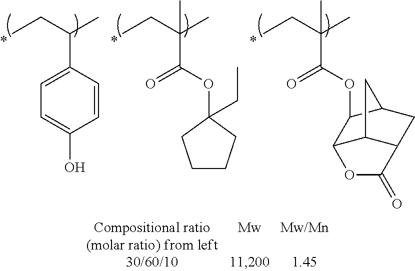

### <Organic Solvent>

MIBC: 4-methyl-2-pentanol
IPA: isopropanol
MEK: methyl ethyl ketone

### <Water>

Ultrapure water

### [Container]

The containers accommodating each chemical liquid are shown below.
HDPE: A container with an interior wall formed of high density polyethylene (HDPE)
PP: A container with an interior wall formed of polypropylene (PP)
PFA: A container with an interior wall formed of perfluoroalkoxyalkane (PFA)
PTFE: A container with an interior wall formed of polytetrafluoroethylene (PTFE)

### [Measurement and Evaluation]

Various measuring methods and evaluation methods will be described in detail below.

### [Contents of Cu and Fe]

The content of each metal atom of Cu and Fe contained in the chemical liquid was measured under the following measurement conditions.

The chemical liquid of each of Examples and Comparative Examples was measured using an Agilent 8800 triple quadrupole ICP-MS (for semiconductor analysis, option #200).

### (Measurement Conditions)

The sample introduction system used a quartz torch, a coaxial perfluoroalkoxyalkane (PFA) nebulizer (for self-suction), and a platinum interface cone. The measurement parameters of cool plasma conditions are as follows.
Radio frequency (RF) output (W): 600
Carrier gas flow rate (L/min): 0.7
Makeup gas flow rate (L/min): 1
Sampling depth (mm): 18

### [Contact Angle]

According to the following procedure, a coating film containing the compound A was formed on a substrate using each of the chemical liquids of Examples 1 to 15 and Comparative Examples 2 to 9, and the contact angle with respect to water on the surface of the formed coating film was evaluated. In Comparative Example 1, a treatment of bringing the chemical liquid into contact with the substrate was not carried out.

First, a commercially available silicon wafer (12 inches in diameter) was prepared as the substrate. Next, a tungsten layer was formed on one surface of the silicon wafer by CVD to prepare a wafer with a W layer. In addition, another silicon wafer was prepared, and a ruthenium layer was formed on the surface of the silicon wafer by CVD to prepare a wafer with a Ru layer. Further, another silicon wafer was prepared, and a SiO₂ layer was formed on the surface of the silicon wafer by plasma CVD using tetraethoxysilane (TEOS) as a precursor to prepare a wafer with a SiO₂ layer. The CVD treatment time was adjusted so that the thickness of each of the tungsten layer and the ruthenium layer was 20 nm.

The prepared wafer with a W layer, wafer with a Ru layer, and wafer with a SiO₂ layer were cut into 2 cm square pieces, and each cut wafer was immersed in each chemical liquid placed in a container. Each wafer was immersed in the chemical liquid while stirring the chemical liquid under the condition of 250 rpm using a magnetic stirrer. The temperature of the chemical liquid during the immersion was 25° C., and the immersion time was 10 minutes.

Regarding the wafer with a W layer, the above immersion was carried out after carrying out the following pretreatment.

The wafer with a W layer was immersed in a 1% by mass citric acid aqueous solution placed in a container. The immersion in the citric acid aqueous solution was carried out while stirring the citric acid aqueous solution with a magnetic stirrer under the condition of 250 rpm. The temperature of the citric acid aqueous solution during the immersion was 25° C., and the immersion time was 1 minute. After the immersion, the wafer with a W layer was dried by blowing nitrogen gas.

Next, each wafer immersed in the chemical liquid was subjected to a heating treatment. The heating treatment was carried out using a hot plate under conditions of a heating temperature of 120° C. and a heating time of 5 minutes.

After the heating treatment, a rinsing treatment was carried out using isopropyl alcohol (IPA). The rinsing treatment was carried out by immersing the wafer after the heating treatment in IPA placed in a container. The above-mentioned immersion was carried out while stirring IPA with a magnetic stirrer under the condition of 250 rpm. The temperature of IPA during the immersion was 25° C., and the immersion time was 30 seconds.

After the rinsing treatment, each wafer was dried by blowing nitrogen gas.

A sample of a modified substrate with a coating film formed on each wafer was obtained through the above treatment.

The contact angle of the sample of the modified substrate obtained by the above method with respect to water was measured by the following method.

The measurement was carried out in an environment of 23° C. using a contact angle meter (“DMs-501”, manufactured by Kyowa Interface Science Co., Ltd.). The value 500 milliseconds after the liquid droplet of water came into contact with the surface was measured three times, and an average value of the measured values was taken as the contact angle. The analysis was carried out with a surface tension of water being 72.9 mN/m.

Note that the contact angle was measured for each sample of the modified substrates formed using the wafer with a W layer and the wafer with a Ru layer.

In addition, for the sample of the modified substrate of Comparative Example 1, the contact angle with respect to water was measured on the surfaces of the formed W layer and Ru layer.

### [Thickness of Oxide Film]

The sample of the modified substrate was subjected to a treatment for forming an oxide film by ALD according to the following procedure, and the deposition selectivity of the oxide film was evaluated.

First, a sample of a modified substrate was prepared in the same manner as in the above-mentioned method for measuring a contact angle, and for the obtained sample, an aluminum oxide film was formed on the coating film of the sample using an atomic layer deposition system (“AD-230LP”, manufactured by Samco Inc.) to obtain a laminate.

Trimethylaluminum was used as an organic metal raw material, and oxygen plasma was used in an oxidation treatment. The temperature of the ALD treatment was 200° C. In addition, in each of Examples and Comparative Examples, the sample of the modified substrate formed of a silicon wafer was subjected to the ALD treatment so that the film thickness of the aluminum oxide film formed was 5 nm. Samples of modified substrates formed of a wafer with a W layer and a wafer with a Ru layer were also subjected to the ALD treatment under the same conditions as those in which an aluminum oxide film having a film thickness of 5 nm was formed in a case where this sample of the modified substrate formed of a silicon wafer was used.

The film thickness of the aluminum oxide film of each sample after the ALD treatment was measured using a spectroscopic ellipsometer (M-2000XI, manufactured by J.A. Woollam Japan, Co., Inc.). The film thickness was measured at 5 points of the sample, and an arithmetic average value of the obtained measured values was taken as the film thickness. The measurement was carried out with a measurement range of 1.2 to 2.5 eV and a measurement angle of 70° and 75°.

### [Surface Roughness Ra]

The surface roughness (arithmetic average roughness Ra) of the aluminum oxide film laminated on the sample of the modified substrate by the above method was measured using an atomic force microscope (AFM) according to the method described in JIS B 0601-2001.

### [Results]

Tables 1 to 3 show the composition of the chemical liquid, the container, and the evaluation results.

In the tables, the column of “Container” shows a material constituting the interior wall of the container that accommodates the chemical liquid in each of Examples.

In the tables, the column of “Amount (%)” of “Compound A” shows the content (% by mass) of the compound A with respect to the total mass of the chemical liquid. The content of the organic solvent was the remainder of the chemical liquid excluding the compound A, the specific metal atoms, and water. In addition, in Example 13, a mixed solvent of isopropanol (IPA) and 4-methyl-2-pentanol (MIBC) at a mass ratio of 1:1 was used as the organic solvent.

The column of “Cu (ppt)” and the column of “Fe (ppt)” show the content (ppt by mass) of each metal atom with respect to the total mass of the chemical liquid measured by the above-mentioned method.

The column of “Compound A/specific metal atom” shows the ratio (mass ratio) of the content of the compound A to the total content of the specific metal atoms (Cu and Fe). The notation of “E+n” in the numerical values in the column of “Compound A/specific metal atom” means “×10ⁿ”. n represents a natural number.

The column of “Water (%)” shows the content (% by mass) of water with respect to the total mass of the chemical liquid.

In the tables, the column labeled “W” shows each evaluation result in a case where the above-mentioned wafer with a W layer was used, the column labeled “Ru” shows each evaluation result in a case where the above-mentioned wafer with a Ru layer was used, and the column labeled “SiO₂” shows each evaluation result in a case where the above-mentioned silicon wafer was used.

The column of “Contact angle) (°” shows the contact angle) (° with respect to water on the surface of the coating film of the sample of each modified substrate evaluated by the above-mentioned method.

The column of “AlOx film thickness (nm)” shows the film thickness (unit: nm) of the aluminum oxide film formed on the coating film of the sample of each modified substrate, measured by the above-mentioned method, and the column of “AlOx surface, Ra (nm)” shows the arithmetic average roughness Ra (unit: nm) of the aluminum oxide film measured by the above-mentioned method. The notation of “<1” in the column of “AlOx surface, Ra (nm)” means that the arithmetic average roughness Ra was less than 1 nm.

In addition, the column marked with “−” indicates that the value cannot be calculated.

TABLE 1

| | | | Example 1 | Example 2 | Example 3 | Example 4 |
|---|---|---|---|---|---|---|
| Container | | | HDPE | HDPE | HDPE | HDPE |
| Composition | Compound | Type | A-1 | A-2 | A-3 | A-1 |
| of chemical | A | Amount (%) | 0.01 | 0.1 | 0.1 | 0.1 |
| liquid | Organic solvent | | MIBC | IPA | MIBC | MIBC |
| | Specific | Cu (ppt) | 120 | 0.1 | 200 | 220 |
| | metal atom | Fe (ppt) | 10 | 11 | 80 | 450 |
| | Compound A/specific metal atom | | 7.7E+05 | 9.0E+07 | 3.6E+06 | 1.5E+06 |
| | Water (%) | | 0.2 | 0.1 | 0.05 | 0.1 |
| Evaluation | W | Contact angle (°) | 96 | 101 | 100 | 105 |
| test | | AlOx film thickness (nm) | 1.0 | 0.9 | 0.8 | 0.7 |
| | | AlOx surface, Ra (nm) | 0.6 | 0.7 | 0.8 | 0.4 |
| | Ru | Contact angle (°) | 97 | — | 95 | 97 |
| | | AlOx film thickness (nm) | 0.7 | — | 0.5 | 0.6 |
| | | AlOx surface, Ra (nm) | 0.4 | — | 0.3 | 0.3 |
| | SiO₂ | AlOx film thickness (nm) | 5.0 | 5.0 | 5.0 | 5.0 |
| | | AlOx surface, Ra (nm) | 0.2 | 0.1 | 0.1 | 0.1 |
| | | | Example 5 | Example 6 | Example 7 | Example 8 |
| Container | | | HDPE | HDPE | PP | HDPE |
| Composition | Compound | Type | A-4 | A-5 | A-6 | A-7 |
| of chemical | A | Amount (%) | 0.1 | 0.1 | 0.1 | 0.1 |
| liquid | Organic solvent | | MIBC | MIBC | IPA | IPA |
| | Specific | Cu (ppt) | 110 | 560 | 430 | 800 |
| | metal atom | Fe (ppt) | 120 | 300 | 44 | 100 |
| | Compound A/specific metal atom | | 4.3E+06 | 1.2E+06 | 2.1E+06 | 1.1E+06 |
| | Water (%) | | 0.2 | 0.4 | 0.2 | 0.3 |
| Evaluation | W | Contact angle (°) | 94 | 67 | 90.8 | 56 |
| test | | AlOx film thickness (nm) | 1.1 | 3.1 | 1.0 | 3.7 |
| | | AlOx surface, Ra (nm) | 0.7 | 0.5 | 0.9 | 0.5 |
| | Ru | Contact angle (°) | 82 | 60 | — | — |
| | | AlOx film thickness (nm) | 1.9 | 2.5 | — | — |
| | | AlOx surface, Ra (nm) | 0.4 | 0.4 | — | — |
| | SiO₂ | AlOx film thickness (nm) | 5.0 | 5.0 | 5.0 | 5.0 |
| | | AlOx surface, Ra (nm) | 0.3 | 0.1 | 0.1 | 0.1 |

TABLE 2

| | | | Example 9 | Example 10 | Example 11 | Example 12 |
|---|---|---|---|---|---|---|
| Container | | | PFA | HDPE | PTFE | HDPE |
| Composition | Compound A | Type | A-8 | A-9 | A-2 | A-10 |
| of chemical | | Amount (%) | 0.1 | 0.1 | 0.1 | 0.1 |
| liquid | Organic solvent | | IPA | IPA | IPA | IPA |
| | Specific metal | Cu (ppt) | 280 | 89 | 88 | 600 |
| | atom | Fe (ppt) | 150 | 201 | 402 | 400 |
| | Compound A/specific metal atom | | 2.3E+06 | 3.4E+06 | 2.0E+06 | 1.0E+06 |
| | Water (%) | | 0.05 | 0.1 | 0.1 | 0.2 |
| Evaluation | W | Contact angle (°) | 50 | 75 | 107 | 76 |
| test | | AlOx film thickness (nm) | 3.8 | 1.8 | 0.8 | 1.5 |
| | | AlOx surface, Ra (nm) | 0.9 | 0.8 | 0.7 | 0.7 |
| | Ru | Contact angle (°) | — | — | — | — |
| | | AlOx film thickness (nm) | — | — | — | — |
| | | AlOx surface, Ra (nm) | — | — | — | — |
| | SiO₂ | AlOx film thickness (nm) | 5.0 | 5.0 | 5.0 | 5.0 |
| | | AlOx surface, Ra (nm) | 0.2 | 0.1 | 0.1 | 0.1 |

| | | | Example 13 | Example 14 | Example 15 |
|---|---|---|---|---|---|
| Container | | | HDPE | HDPE | HDPE |
| Composition | Compound A | Type | A-7 | A-1 | A-2 |
| of chemical | | Amount (%) | 0.1 | 0.2 | 0.1 |
| liquid | Organic solvent | | IPA:MIBC | MIBC | MEK |
| | | | (1:1) | | |
| | Specific metal | Cu (ppt) | 400 | 400 | 100 |
| | atom | Fe (ppt) | 100 | 200 | 300 |
| | Compound A/specific metal atom | | 2.0E+06 | 3.3E+06 | 2.5E+06 |
| | Water (%) | | 0.3 | 0.3 | 0.2 |
| Evaluation | W | Contact angle (°) | 66 | 108 | 100 |
| test | | AlOx film thickness (nm) | 2.9 | 0.6 | 0.9 |
| | | AlOx surface, Ra (nm) | 0.7 | 0.5 | 0.7 |
| | Ru | Contact angle (°) | — | — | — |
| | | AlOx film thickness (nm) | — | — | — |
| | | AlOx surface, Ra (nm) | — | — | — |
| | SiO₂ | AlOx film thickness (nm) | 5.0 | 5.0 | 5.0 |
| | | AlOx surface, Ra (nm) | 0.1 | 0.1 | 0.1 |

TABLE 3

| | | | Comparative | Comparative | Comparative | Comparative | Comparative |
|---|---|---|---|---|---|---|---|
| | | | Example 1 | Example 2 | Example 3 | Example 4 | Example 5 |
| Container | | | — | HDPE | HDPE | HDPE | HDPE |
| Composition | Compound | Type | | C-1 | A-3 | A-4 | A-2 |
| of chemical | A | Amount (%) | | 0.1 | 0.1 | 0.1 | 0.00001 |
| liquid | Organic solvent | | | MIBC | MIBC | MIBC | IPA |
| | Specific | Cu (ppt) | | 100 | 140 | 1220 | 30 |
| | metal atom | Fe (ppt) | | 200 | 1200 | 220 | 0 |
| | Compound A/specific metal atom | | | 3.3E+06 | 7.5E+05 | 6.9E+05 | 3.3E+03 |
| | Water (%) | | | 0.3 | 0.5 | 0.3 | 0.2 |
| Evaluation | W | Contact angle (°) | 23 | 32 | 100 | 94 | 100 |
| | | AlOx film thickness (nm) | 5.1 | 4.8 | 1.2 | 2.1 | 1.1 |
| | | AlOx surface, Ra (nm) | 0.8 | 0.7 | 1.2 | 2.2 | 4.9 |
| | Ru | Contact angle (°) | 51 | 56 | 95 | 82 | — |
| | | AlOx film thickness (nm) | 5.3 | 5.3 | 0.8 | 1.7 | — |
| | | AlOx surface, Ra (nm) | 0.8 | 0.6 | 0.8 | 0.7 | — |
| | SiO₂ | AlOx film thickness (nm) | 5.0 | 5.0 | 5.0 | 5.0 | 5.0 |
| | | AlOx surface, Ra (nm) | 0.1 | 0.1 | 0.1 | 0.1 | 0.1 |

| | | | Comparative | Comparative | Comparative | Comparative |
|---|---|---|---|---|---|---|
| | | | Example 6 | Example 7 | Example 8 | Example 9 |
| Container | | | HDPE | HDPE | HDPE | HDPE |
| Composition | Compound | Type | A-4 | A-3 | A-1 | A-1 |
| of chemical | A | Amount (%) | 5 | 0.1 | 0.001 | 0.002 |
| liquid | Organic solvent | | MIBC | MIBC | MIBC | MIBC |
| | Specific | Cu (ppt) | 13 | 200 | 80 | 950 |
| | metal atom | Fe (ppt) | 21 | 80 | 100 | 1100 |
| | Compound A/specific metal atom | | 1.5E+09 | 3.6E+06 | 5.6E+04 | 9.8E+03 |
| | Water (%) | | 0.4 | 2.0 | 0.1 | 0.1 |
| Evaluation | W | Contact angle (°) | 94 | 100 | 88 | 88 |
| | | AlOx film thickness (nm) | 1.1 | 5.0 | 2.3 | 2.1 |
| | | AlOx surface, Ra (nm) | 1.9 | 0.8 | 2.0 | 1.7 |
| | Ru | Contact angle (°) | 81 | 95 | 97 | 93 |
| | | AlOx film thickness (nm) | 2.0 | 0.5 | 0.7 | 0.8 |
| | | AlOx surface, Ra (nm) | 2.9 | 0.6 | 0.7 | 0.7 |
| | SiO₂ | AlOx film thickness (nm) | 5.0 | 5.0 | 5.0 | 5.0 |
| | | AlOx surface, Ra (nm) | 0.1 | 0.1 | 0.1 | 0.1 |

As is clear from the results in the tables above, it was confirmed that the chemical liquid according to the embodiment of the present invention prepared in each of Examples 1 to 15 was capable of forming an ALD film in a region targeted for ALD film formation and was capable of suppressing the formation of an ALD film in a region not targeted for ALD film formation, in a case where an ALD treatment is carried out after bringing the chemical liquid into contact with a predetermined substrate to form a modified film.

On the other hand, in Comparative Example 1 in which the substrate was not treated using the chemical liquid, Comparative Example 2 in which the chemical liquid not containing the compound A was used, and Comparative Example 8 in which the content of the compound A was 10 ppm by mass or less with respect to the total mass of the chemical liquid, the thickness of the ALD film formed on the W-containing region or the Ru-containing region and the thickness of the ALD film formed on the SiO₂ region were approximately the same, and the above-mentioned effects could not be obtained. In addition, in Comparative Examples 3 and 4 in which the content of the specific metal atom was more than a predetermined range, Comparative Examples 5, 6, and 9 in which the ratio of the content of the compound A to the content of the specific metal atom was more than a predetermined range, and Comparative Example 7 in which the content of water was more than 1% by mass with respect to the total mass of the chemical liquid, the surface roughness of the ALD film formed on the W-containing region or the Ru-containing region was equal to or greater than the film thickness. This indicates that an ALD film or partial ALD film with large surface asperities was formed, and from the viewpoint of forming a fine pattern, it cannot be said that the formation of the ALD film could be suppressed.

The chemical liquid container of each of Examples was stored at 40° C. for 3 months after being filled, and then according to the evaluation test procedure described in the section of [Contact angle], a coating film containing the compound A was formed on a substrate and the contact angle with respect to water on the surface of the formed coating film was evaluated. As a result, in the chemical liquid container of Example 9 in which the interior wall of the container was formed of PFA and the chemical liquid container of Example 11 in which the interior wall of the container was formed of PTFE, the measured value of the contact angle before and after storage did not change, but in the chemical liquid containers of Examples other than Examples 9 and 11, the measured value of the contact angle was lower than before storage.

What is claimed is:

1. A chemical liquid for manufacturing a semiconductor, comprising:
a compound A having at least one functional group selected from the group consisting of a nitrogen-containing group, a phosphate group, a phosphonate group, a sulfo group, a carboxy group, a thiol group, and a hydroxy group;
an organic solvent; and
at least one specific metal atom selected from the group consisting of Cu and Fe,
wherein, in a case where the compound A has a hydroxy group, the compound A has at least one group selected from the group consisting of a nitrogen-containing group, a phosphate group, a phosphonate group, a sulfo group, a carboxy group, a thiol group, and an alkyl group having 8 or more carbon atoms which may have a substituent,
a content of the compound A is more than 10 ppm by mass with respect to a total mass of the chemical liquid,
a total content of the specific metal atom is 1,000 ppt by mass or less with respect to the total mass of the chemical liquid,
a mass ratio of the content of the compound A to the total content of the specific metal atom is 10⁴ to 10⁹, and
a content of water contained in the chemical liquid is 1% by mass or less.

2. The chemical liquid according to claim 1,
wherein the compound A has a molecular weight of 600 or less.

3. The chemical liquid according to claim 1,
wherein the compound A has an alkyl group having 8 or more carbon atoms which may have a substituent.

4. The chemical liquid according to claim 1,
wherein the compound A has an alkyl group having 12 or more carbon atoms which may have a substituent.

5. The chemical liquid according to claim 1,
wherein the compound A is a compound represented by Formula (1),
X-L-Y (1)
in the formula, X represents a group having the functional group,
L represents a single bond or a divalent linking group, and
Y represents an alkyl group which may have a substituent.

6. The chemical liquid according to claim 1,
wherein the compound A is a high-molecular-weight compound.

7. The chemical liquid according to claim 1,
wherein the content of the compound A is 0.01% to 10% by mass with respect to the total mass of the chemical liquid.

8. The chemical liquid according to claim 1,
wherein the mass ratio of the content of the compound A to the total content of the specific metal atom is 10⁵ to 10⁸.

9. The chemical liquid according to claim 1,
wherein the chemical liquid is used for treating a semiconductor substrate having a plurality of regions consisting of different materials on a surface thereof.

10. The chemical liquid according to claim 9,
wherein the semiconductor substrate is a semiconductor substrate having a metal region containing tungsten, ruthenium, or molybdenum and an insulating region containing a silicon oxide or a silicon nitride on the surface thereof.

11. A manufacturing method of a modified substrate, comprising:
a step A of bringing the chemical liquid according to claim 1 into contact with a substrate having a plurality of regions consisting of different materials on a surface thereof to form a coating film on at least one region of the plurality of regions.

12. The manufacturing method of a modified substrate according to claim 11,
wherein the substrate is a substrate having an insulating region containing silicon atoms and a metal region containing metal atoms on the surface thereof, and
the coating film is formed on the metal region by the step A.

13. The manufacturing method of a modified substrate according to claim 11,
wherein the step A is a step of bringing the chemical liquid into contact with the substrate to form the coating film, and
the manufacturing method further comprises:
a step B of heating the coating film formed in the step A; and
a step C of subjecting the coating film heated in the step B to a rinsing treatment.

14. A manufacturing method of a laminate, comprising:
a step of forming a metal film containing metal atoms by atomic layer deposition on a region of a surface of a modified substrate manufactured by the manufacturing method according to claim 11, the region being different from a region on which a coating film is formed.

15. The manufacturing method of a laminate according to claim 14, further comprising:
a step of removing the coating film from the laminate on which the metal film is formed.

16. A chemical liquid container comprising:
a container; and
the chemical liquid according to claim 1 that is accommodated in the container.

17. The chemical liquid container according to claim 16,
wherein at least a part of an interior wall of the container is formed of a material selected from the group consisting of high density polyethylene, polypropylene, perfluoroalkoxyalkane, polytetrafluoroethylene, and stainless steel.

18. The chemical liquid according to claim 2,
wherein the compound A has an alkyl group having 8 or more carbon atoms which may have a substituent.

19. The chemical liquid according to claim 2,
wherein the compound A has an alkyl group having 12 or more carbon atoms which may have a substituent.

20. The chemical liquid according to claim 2,
wherein the compound A is a compound represented by Formula (1),
X-L-Y (1)
in the formula, X represents a group having the functional group,
L represents a single bond or a divalent linking group, and
Y represents an alkyl group which may have a substituent.
